(19) United States
(12) Patent Application Publication
(10) Pub. No.: US 2025/0311245 A1
(43) Pub. Date: Oct. 2, 2025

(54) SEMICONDUCTOR DEVICE AND MANUFACTURING METHOD OF SEMICONDUCTOR DEVICE

(71) Applicant: SK hynix Inc., Gyeonggi-do (KR)

(72) Inventors: Hui Woo PARK, Gyeonggi-do (KR); Eun Seok CHOI, Gyeonggi-do (KR)

(21) Appl. No.: 18/780,492

(22) Filed: Jul. 23, 2024

(30) Foreign Application Priority Data
Mar. 26, 2024 (KR) 10-2024-0041142

(51) Int. Cl. H10B 80/00; H01L 23/00; H01L 25/00; H01L 25/065; H01L 25/18; H10B 41/27; H10B 43/27

(52) U.S. Cl. CPC H10B 80/00; H01L 24/08; H01L 24/80; H01L 25/0657; H01L 25/18; H01L 25/50; H10B 41/27; H10B 43/27; H01L 2224/08145; H01L 2224/80895; H01L 2224/80896; H01L 2924/1431; H01L 2924/14511

(57) ABSTRACT

A semiconductor device may include a first gate structure; a second gate structure located over or on the first gate structure; a bonding structure located between the first gate structure and the second gate structure; and a penetration structure extending through the first gate structure, the second gate structure, and the bonding structure.

### CROSS-REFERENCE TO RELATED APPLICATION

This application claims priority under 35 U.S.C. § 119 to Korean Patent Application No. 10-2024-0041142 filed on Mar. 26, 2024, which is incorporated herein by reference in its entirety.

### BACKGROUND

### 1. Technical Field

Embodiments of the present disclosure relate generally to an electronic device and a manufacturing method of the electronic device, and more particularly, to a semiconductor device and a manufacturing method of the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment of the present disclosure, a semiconductor device may include a first gate structure; a second gate structure located over or on the first gate structure; a bonding structure located between the first gate structure and the second gate structure; and a penetration structure extending through the first gate structure, the second gate structure, and the bonding structure.

In an embodiment of the present disclosure, a manufacturing method of a semiconductor device may include forming a first wafer including a first substrate, a first stack disposed on the first substrate, and a first opening and a second opening extending through the first stack; forming a second wafer including a second substrate and a second stack disposed on the second substrate; bonding the first wafer and the second wafer to each other in a state in which the first opening and the second opening are empty; forming third openings extending through the second stack and connected to the first opening; forming fourth openings extending through the second stack and connected to the second opening; forming a first penetration structure in the first opening and the third opening; and forming a second penetration structure in the second opening and the fourth opening.

In an embodiment of the present disclosure, a manufacturing method of a semiconductor device may include forming a first wafer including a first substrate, a first stack disposed on the first substrate, and first channel holes extending through the first stack; forming a second wafer including a second substrate and a second stack disposed on the second substrate; bonding the first wafer and the second wafer to each other in a state in which the first channel holes are empty; removing the second substrate; forming second channel holes extending through the second stack and connected to the first channel holes; and forming channel structures in the first channel holes and the second channel holes.

### BRIEF DESCRIPTION OF THE DRAWINGS

FIG. 1 is a diagram for describing a semiconductor device in accordance with an embodiment of the present disclosure.

FIGS. 2A to 2D are diagrams for describing a manufacturing method of a semiconductor device in accordance with an embodiment of the present disclosure.

FIGS. 3A to 3C are diagrams for describing a manufacturing method of a semiconductor device in accordance with an embodiment of the present disclosure.

FIGS. 4A to 4G are diagrams for describing a manufacturing method of a semiconductor device in accordance with an embodiment of the present disclosure.

FIGS. 5A and 5B are diagrams for describing a manufacturing method of modified embodiments of a gate structure and contact vias of FIG. 4E.

### DETAILED DESCRIPTION

Various embodiments of the present disclosure are directed to a semiconductor device having a stable structure and improved characteristics and a manufacturing method of the semiconductor device.

According to the present technology, it is possible to provide a semiconductor device having a stable structure and improved reliability.

Hereafter, embodiments in accordance with the technical spirit of the present disclosure will be described with reference to the accompanying drawings.

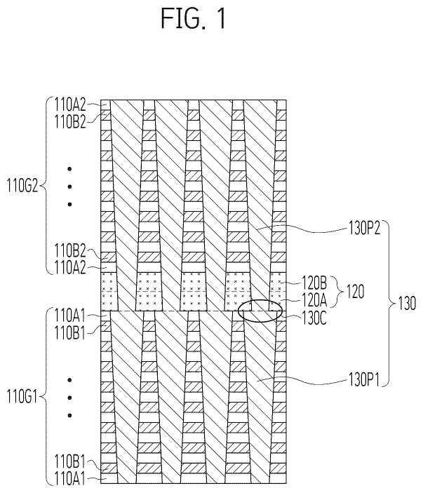

FIG. 1 is a diagram for describing a semiconductor device in accordance with an embodiment of the present disclosure.

Referring to FIG. 1, the semiconductor device may include a first gate structure 110G1, a second gate structure 110G2, a bonding structure 120, and a penetration structure 130.

The first gate structure 110G1 may include first insulating layers 110A1 and first conductive layers 110B1 that are alternately stacked. The first insulating layers 110A1 may each include an insulating material such as, for example, an oxide. The first conductive layers 110B1 may each include a conductive material such as, for example, tungsten, molybdenum, or polysilicon.

The second gate structure 110G2 may be located over or on the first gate structure 110G1. The second gate structure 110G2 may include second insulating layers 110A2 and second conductive layers 110B2 that are alternately stacked. The second insulating layers 110A2 may each include an insulating material such as, for example, an oxide, and the second conductive layers 110B2 may each include a conductive material such as, for example, tungsten, molybdenum, or polysilicon.

The first and second conductive layers 110B1 and 110B2 may be gate lines such as source select lines, word lines, or drain select lines. Source select transistors, memory cells, or drain select transistors may be located in regions where channel structures and the first conductive layers 110B1 intersect each other and also in regions where the channel structures and the second conductive layers 110B2 intersect with each other. As an example, at least one source select transistor, a plurality of memory cells, and at least one drain select transistor that are stacked along the channel structure may constitute one memory string.

The bonding structure 120 may be located between the first and second gate structures 110G1 and 110G2. The bonding structure 120 may include a first bonding layer 120A and a second bonding layer 120B disposed on the first bonding layer 120A. In a manufacturing process of the semiconductor device, the first and second bonding layers 120A and 120B may be bonded to each other. Accordingly, the first and second gate structures 110G1 and 110G2 may be bonded to each other through the bonding structure 120. The bonding structure 120 may include an insulating material such as, for example, an oxide or nitride. For example, the bonding structure 120 may include SiCN (silicon-carbon-nitride). Because the first and second bonding layers 120A and 120B may each include SiCN, the bonding force at the bonding interface may be improved.

For example, an embodiment in which the semiconductor device includes the bonding structure 120 has been illustrated in FIG. 1, but the bonding structure 120 may be omitted and, in such a case, the first and second gate structures 110G1 and 110G2 may be directly bonded to each other. For example, the uppermost first insulating layer 110A1 of the first gate structure 110G1 and the lowermost second insulating layer 110A2 of the second gate structure 110G2 may be bonded to each other.

The penetration structure 130 may extend through the first gate structure 110G1 and the second gate structure 110G2. For example, the penetration structure 130 may extend through the first gate structure 110G1, the second gate structure 110G2, and the bonding structure 120. The penetration structure 130 may include a first portion 130P1 extending through the first gate structure 110G1 and a second portion 130P2 extending through the second gate structure 110G2. In the embodiment of FIG. 1, the second portion 130P2 may extend through the second gate structure 110G2 and the bonding structure 120 and be connected to the first portion 130P1. The penetration structure 130 may have a tapered shape. For example, the first portion 130P1 may have a tapered shape with a decreasing width from an uppermost surface of the first gate structure 110G1 toward a lowermost surface of the first gate structure 110G1. The second portion 130P2 may have a tapered shape with a decreasing width from an uppermost surface of the second gate structure 110G2 toward a lowermost surface of the second gate structure 110G2.

The penetration structure 130 may include an inflection portion 130C located at the uppermost surface of the first gate structure 110G1. For example, the penetration structure 130 may include the inflection portion 130C located between the first gate structure 110G1 and the bonding structure 120. The inflection portion 130C may be located between the first portion 130P1 and the second portion 130P2. The inflection portion 130C may be a portion where an uppermost surface of the first portion 130P1 and a lowermost surface of the second portion 130P2 are connected to each other, and at the inflection portion 130C, the uppermost surface of the first portion 130P1 and the lowermost surface of the second portion 130P2 may have different widths. Accordingly, the penetration structure 130 may have a width that decreases from the uppermost surface of the second gate structure 110G2 toward the lowermost surface of the second gate structure 110G2, increases again at the inflection portion 130C, and decreases again from the uppermost surface of the first gate structure 110G1 toward from the lowermost surface of the first gate structure 110G1.

Although not illustrated in FIG. 1, the penetration structure 130 may include various structures. For example, the penetration structure 130 may include a channel structure, a slit structure, a contact via, a support, a contact plug, and the like. The channel structure may include at least one of a channel layer, a memory layer surrounding the channel layer, and an insulating core located in the channel layer. The slit structure may include at least one of an insulating material, a conductive material, or a semiconductor material. The contact via or the contact plug may include a conductive material such as, for example, tungsten. The support may include an insulating material such as, for example, an oxide. Alternatively, the support may include a dummy channel structure.

According to the structure described above, the semiconductor device may include the bonding structure 120 located between the first and second gate structures 110G1 and 110G2. The first and second gate structures 110G1 and 110G2 may be bonded to each other through the bonding structure 120. The bonding structure 120 may include SiCN. Accordingly, the bonding force at the bonding interface may be improved.

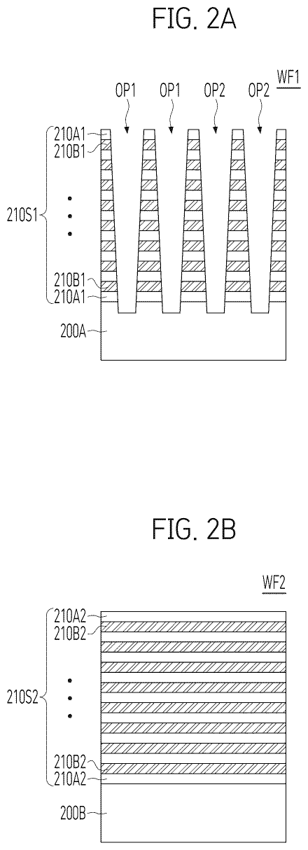

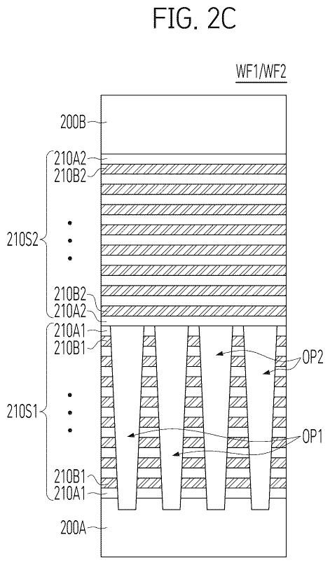

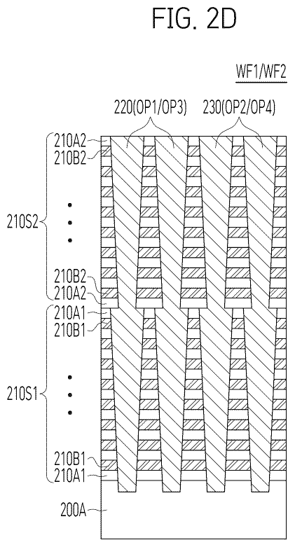

FIGS. 2A to 2D are diagrams for describing a manufacturing method of a semiconductor device in accordance with an embodiment of the present disclosure. Hereinafter, a content overlapping with previously described content may be omitted.

Referring to FIG. 2A, a first wafer WF1 may be formed. First, a first stack 210S1 may be formed on a first substrate 200A. The first stack 210S1 may include first material layers 210A1 and second material layers 210B1 that are alternately stacked. The first material layers 210A1 may each include an insulating material such as, for example, an oxide, and the second material layers 210B1 may each include a sacrificial material such as, for example, nitride.

Subsequently, first openings OP1 and second openings OP2 extending through the first stack 210S1 may be formed. For example, the first openings OP1 and the second openings OP2 may be formed to extend into the first substrate 200A through the first stack 210S1. The first openings OP1 and the second openings OP2 may be formed at the same time or at different times. As an example, when the first openings OP1 are formed, the second openings OP2 may be formed simultaneously with the first openings OP1. As another example, after the first openings OP1 are formed, the second openings OP2 may be formed.

Referring to FIG. 2B, a second wafer WF2 may be formed. First, a second stack 210S2 may be formed on a second substrate 200B. The second stack 210S2 may include third material layers 210A2 and fourth material layers 210B2 that are alternately stacked. The third material layers 210A2 may each include an insulating material such as, for example, an oxide, and the fourth material layers 210B2 may each include a sacrificial material such as, for example, nitride.

Referring to FIG. 2C, the first and second wafers WF1 and WF2 may be bonded to each other. For example, the first and second wafers WF1 and WF2 may be bonded to each other so that the first stack 210S1 and the second stack 210S2 face each other. In such a case as shown in the embodiment of FIG. 2C, the uppermost first material layer 210A1 of the first stack 210S1 and the uppermost third material layer 210A2 of the second stack 21052 may be bonded to each other.

When bonding the first and second wafers WF1 and WF2, the first and second openings OP1 and OP2 may be in an empty state. That is, the first and second wafers WF1 and WF2 may be bonded to each other without forming other material such as a sacrificial material in the first and the second openings OP1 OP2. When a sacrificial material is added in the first and second openings OP1 and OP2, the sacrificial material may not be completely removed in a subsequent process and as a result the shape of structures formed in the first and second openings OP1 and OP2 may be changed and/or defects such as particle bridges may occur. By contrast, according to an embodiment of the present disclosure, the subsequent process is performed with the first and second openings OP1 and OP2 being empty, and it is, thus, possible to reduce or even fully prevent any defects from occurring in the process of forming and removing the sacrificial material and/or the like.

Referring now to FIG. 2D, first and second penetration structures 220 and 230 may be formed. A third opening OP3 extending through the second stack 210S2 and connected to the first opening OP1 may be formed. A fourth opening OP4 extending through the second stack 210S2 and connected to the second opening OP2 may be formed. The third and fourth openings OP3 and OP4 may be formed at the same time or at different times. As an example, when the third opening OP3 is formed, the fourth opening OP4 may be formed. As another example, after the third opening OP3 is formed, the fourth opening OP4 may be formed.

The third opening OP3 or the fourth opening OP4 may be formed in a state in which the sacrificial material or the like is not formed in the first and second openings OP1 and OP2. For example, after the third or the fourth openings OP3 or OP4 is formed, there is no need to remove the sacrificial material or the like in the first or the second openings OP1 or OP2. Accordingly, it is possible to reduce or prevent defects occurring when removing the sacrificial material or the like.

Each of the first penetration structures 220 may be formed in a first opening OP1 and a third opening OP3. The second penetration structure 230 may be formed in a second opening OP2 and a fourth opening OP4. The first and second penetration structures 220 and 230 may be formed at the same time or at different times. As an example, when the first penetration structure 220 is formed, the second penetration structure 230 may be formed. As another example, the second penetration structure 230 may be formed after the first penetration structure 220 is formed.

Although not illustrated in FIG. 2D, the first and second penetration structures 220 and 230 may include various structures. For example, the first and second penetration structures 220 and 230 may each include a channel structure, a slit structure, a contact via, a support, a contact plug, and the like. The channel structure may include at least one of a channel layer, a memory layer surrounding the channel layer, and an insulating core located in the channel layer. The slit structure may include at least one of an insulating material, a conductive material, or a semiconductor material. The contact via or the contact plug may include a conductive material such as, for example, tungsten. The support may include an insulating material such as, for example, an oxide.

According to the manufacturing method described above, when the first openings OP1 are formed, the second openings OP2 may be formed. When the third openings OP3 are formed, the fourth openings OP4 may be formed. Accordingly, the processes may be unified, and through this, a manufacturing cost of the semiconductor device may be reduced.

The first and second wafers WF1 and WF2 may be bonded to each other in a state in which the first and second openings OP1, and OP2 formed in the first stack 210S1 are empty. In addition, the third and fourth openings OP3 and OP4 may be formed in a state in which the first and second openings OP1, and OP2 are empty. In such a case, the sacrificial material is not formed in the first and second openings OP1, and OP2, and it is thus possible to reduce or prevent the defects occurring in the process of forming and removing the sacrificial material.

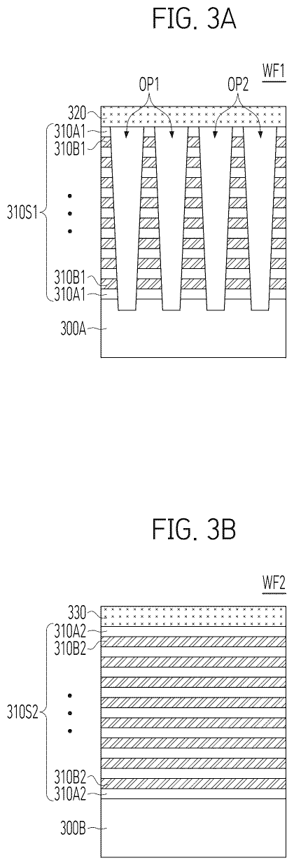

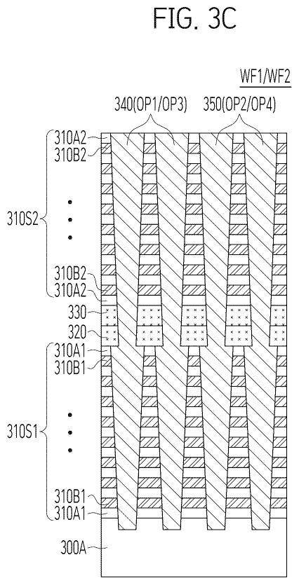

FIGS. 3A to 3C are diagrams for describing a manufacturing method of a semiconductor device in accordance with an embodiment of the present disclosure. Hereinafter, content overlapping with previously described content may be omitted.

Referring to FIG. 3A, a first wafer WF1 may be formed including a first substrate 300A, a first stack 310S1 disposed on the first substrate 300A, first and second openings OP1 and OP2 extending through the first stack 310S1, and a first bonding layer 320 disposed on the first stack 310S1.

The first stack 310S1 may be formed by alternately stacking first material layers 310A1 and second material layers 310B1 on the first substrate 300A. The first material layers 310A1 may each include an insulating material such as, for example, an oxide, and the second material layers 310B1 may each include a sacrificial material such as, for example, nitride.

Subsequently, the first and second openings OP1, and OP2 may be formed to extend through the first stack 310S1. When the first openings OP1 are formed, the second openings OP2 may be formed at the same time. The first and second openings OP1, and OP2 may be formed by a unified process, and thus, a manufacturing cost of the semiconductor device may be reduced.

Subsequently, the first bonding layer 320 may be formed on the first stack 310S1. For example, the first bonding layer 320 may be formed in a state in which the first and second openings OP1, and OP2 are empty. In such a case, the first bonding layer 320 may protrude into the first and second openings OP1, and OP2. The first bonding layer 320 may reduce or prevent entry of foreign substances or the like into the first and second openings OP1, and OP2 in a manufacturing process of the semiconductor device. The first bonding layer 320 may include an insulating material such as, for example, an oxide or nitride. For example, the first bonding layer 320 may include SiCN.

Referring to FIG. 3B, a second wafer WF2 including a second substrate 300B, a second stack 31052 disposed on the second substrate 300B, and a second bonding layer 330 disposed on the second stack 310S2 may be formed.

The second stack 310S2 may be formed by alternately stacking third material layers 310A2 and fourth material layers 310B2 on the second substrate 300B. The third material layers 310A2 may each include an insulating material such as, for example, an oxide, and the fourth material layers 310B2 may each include a sacrificial material such as, for example, nitride.

Subsequently, the second bonding layer 330 may be formed on the second stack 310S2. The second bonding layer 330 may include an insulating material such as, for example, an oxide or nitride. For example, the second bonding layer 330 may include SiCN.

Referring to FIG. 3C, the first and second wafers WF1 and WF2 may be bonded to each other. For example, the first and second wafers WF1 and WF2 may be bonded to each other so that the first stack 310S1 and the second stack 310S2 face each other. In such a case, the first bonding layer 320 and the second bonding layer 330 may be bonded to each other. Because the first bonding layer 320 and the second bonding layer 330 may each include SiCN, the bonding force at a bonding interface may be improved.

Subsequently, third openings OP3 extending through the second stack 310S2 and connected to the first openings OP1 may be formed. Fourth openings OP4 extending through the second stack 310S2 and connected to the second openings OP2 may be formed. The third and fourth openings OP3 and OP4 may be formed at the same time or at different times. For example, when the third openings OP3 are formed, the fourth openings OP4 may be formed at the same time. For example, in a process of forming the third and fourth openings OP3 and OP4, the first bonding layer 320 protruding into the first and second openings OP1, and OP2 may be removed.

Because the first or second openings OP1 or OP2 are in a state in which they are empty, there is no need to remove a sacrificial material or the like after forming the third openings OP3 or the fourth openings OP4. There is no need to perform an additional process for opening the first or second openings OP1 or OP2 Accordingly, it is possible to reduce or prevent defects occurring in a process of removing the sacrificial material or the like.

Subsequently, first and second penetration structures 340 and 350 may be formed. The first penetration structure 340 may be formed in the first opening OP1 and the third opening OP3. The second penetration structure 350 may be formed in the second opening OP2 and the fourth opening OP4. The first penetration structure 340 and the second penetration structure 350 may be formed at the same time or at different times. As an example, when the first penetration structure 340 is formed, the second penetration structure 350 may be formed. As another example, after the first penetration structure 340 is formed, the second penetration structure 350 may be formed.

Although not illustrated in FIG. 3C, the first penetration structure 340 and the second penetration structure 350 may include various structures. For example, the first penetration structure 340 and the second penetration structure 350 may each include a channel structure, a slit structure, a contact via, a support, a contact plug, and the like.

According to the manufacturing method described above, a subsequent process may be performed in a state in which the first and second openings OP1, and OP2 formed in the first stack 310S1 are empty. In such a case, the sacrificial material or the like is not formed in the first and second openings OP1, and OP2, and it is thus possible to reduce or prevent defects occurring in a process of forming and removing the sacrificial material or the like.

The first bonding layer 320 may be formed on the first stack 310S1. Here, the first bonding layer 320 may reduce or prevent the entry of the foreign substances or the like into the first and second openings OP1, and OP2.

In addition, the first bonding layer 320 of the first wafer WF1 and the second bonding layer 330 of the second wafer WF2 may be bonded to each other. Because the first bonding layer 320 and the second bonding layer 330 may each include SiCN, the bonding force at the bonding interface may be improved.

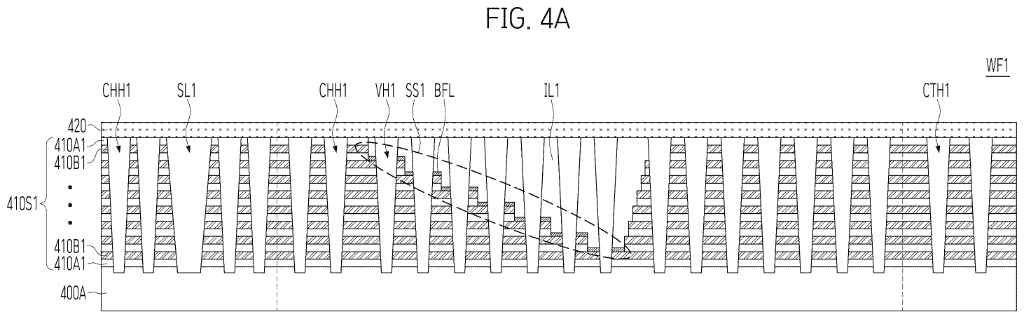

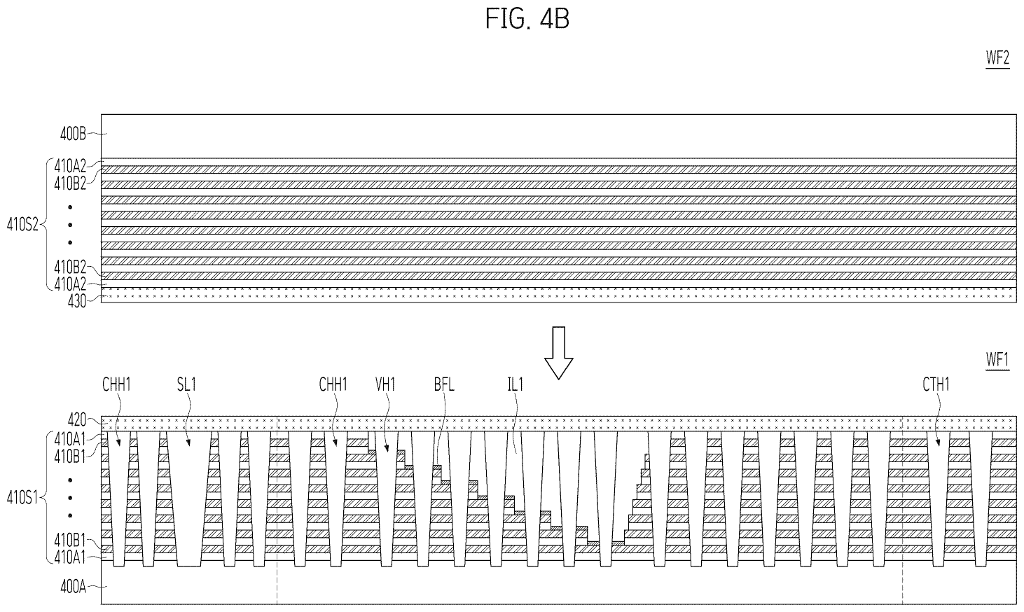

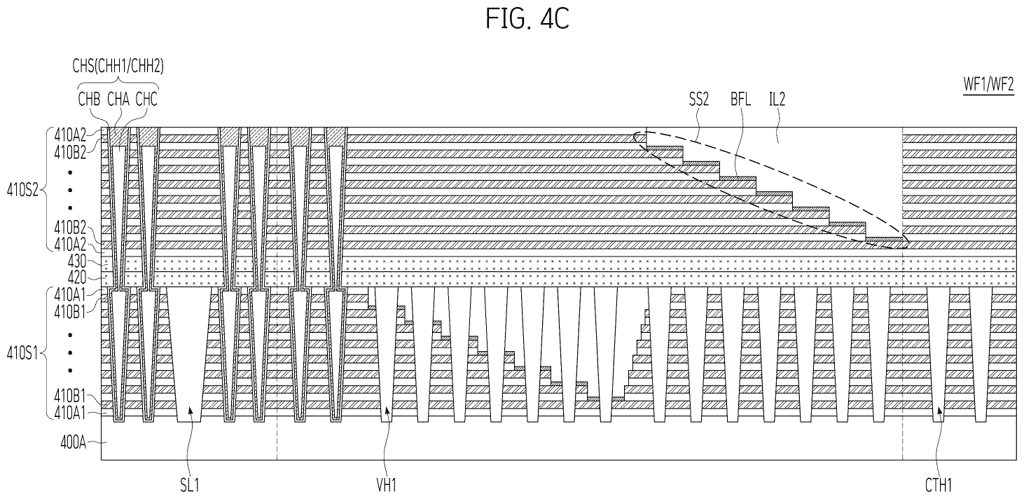

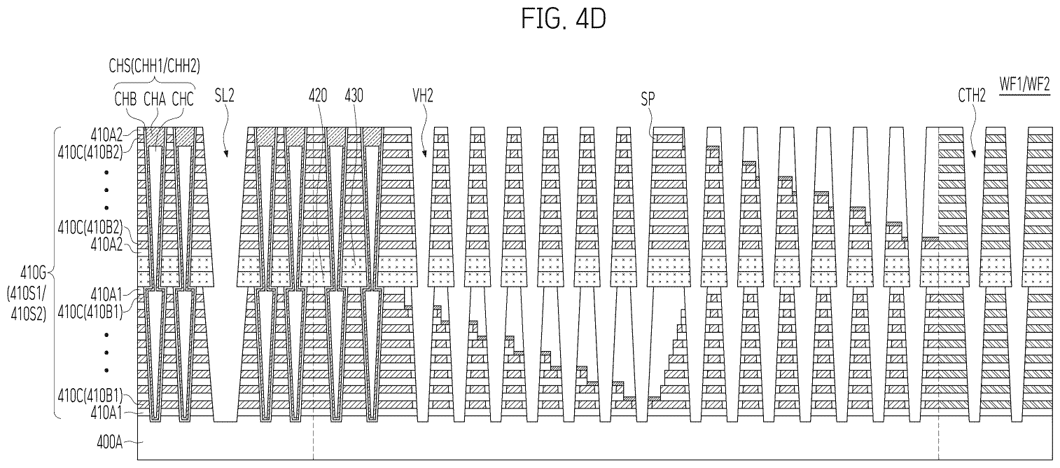

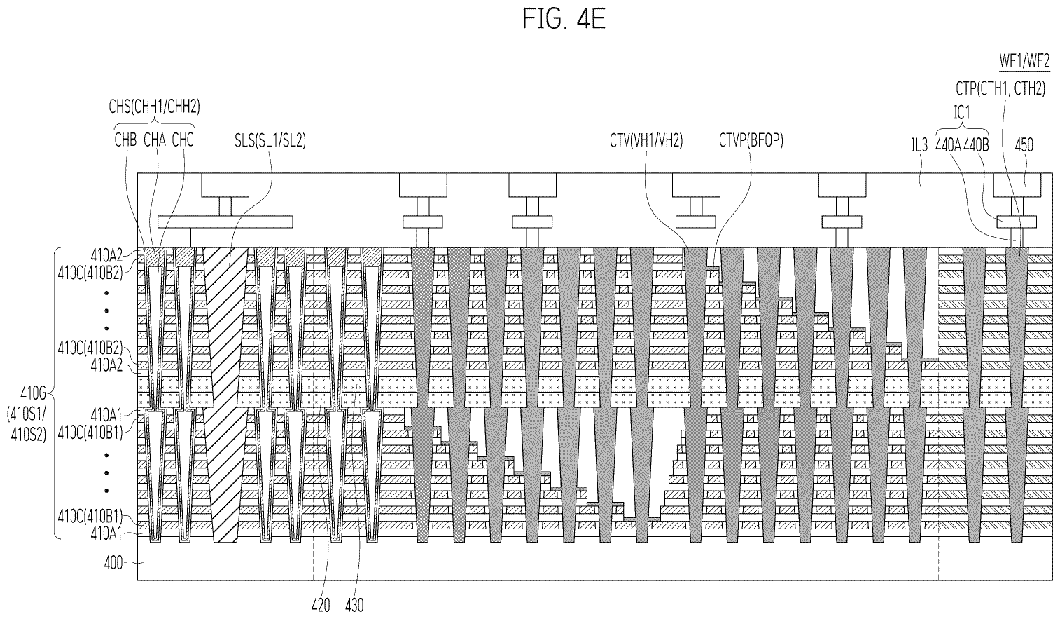

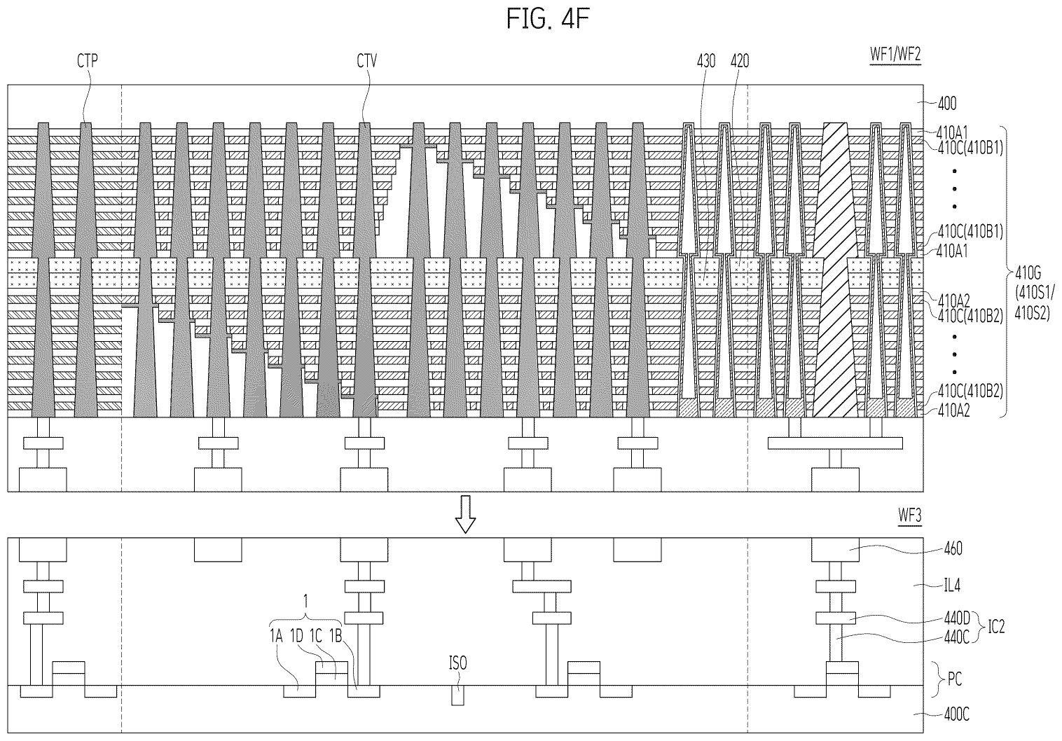

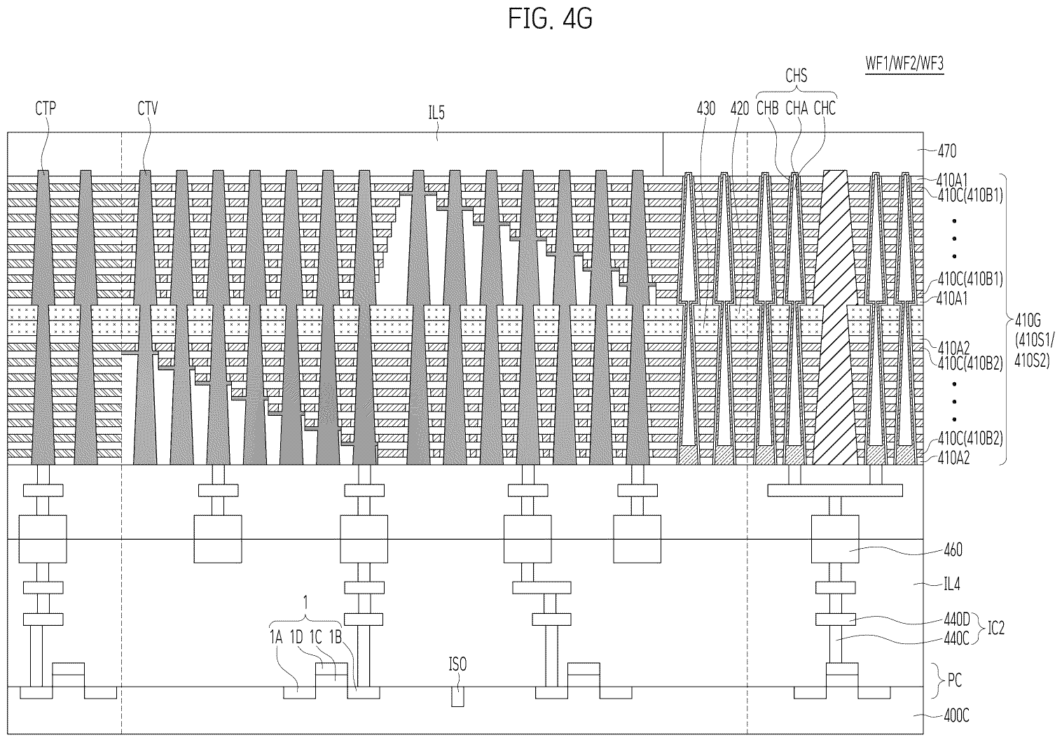

FIGS. 4A to 4G are diagrams for describing a manufacturing method of a semiconductor device in accordance with an embodiment of the present disclosure. Hereinafter, content overlapping with previously described content may be omitted.

Referring to FIG. 4A, a first wafer WF1 may be formed. First, a first stack 410S1 may be formed on a first substrate 400A. The first stack 410S1 may include first material layers 410A1 and second material layers 410B1 that are alternately stacked. The first stack 410S1 may include a first staircase structure SS1. For example, the first stack 410S1 may include the first staircase structure SS1 through which an uppermost surface of at least one of the second material layers 410B1 is exposed. A buffer layer BFL may be formed on the second material layers 410B1 whose uppermost surfaces are exposed. A first interlayer insulating layer IL1 may be formed on the first staircase structure SS1. The buffer layer BFL may include a material having a selectivity with respect to the first material layers 410A1 and the second material layers 410B1. The first interlayer insulating layer IL1 may include an insulating material such as, for example, an oxide.

Subsequently, first channel holes CHH1 extending through the first stack 410S1 may be formed. A first slit SL1 extending through the first stack 410S1 may be formed. The first slit SL1 may be formed between the first channel holes CHH1. When the first channel holes CHH1 are formed, the first slit SL1 may be formed. First via holes VH1 extending through the first stack 410S1 may be formed. The first via holes VH1 may extend through the first staircase structure SS1 of the first stack 410S1. When the first channel holes CHH1 are formed, the first via holes VH1 may be formed. First contact holes CTH1 extending through the first stack 410S1 may be formed. Here, the first contact holes CTH1 may be formed at locations spaced apart from the first channel holes CHH1. When the first channel holes CHH1 are formed, the first contact holes CTH1 may be formed.

According to an embodiment of the present disclosure, when the first channel holes CHH1 are formed, the first slit SL1, the first via holes VH1, and the first contact holes CTH1 may be formed simultaneously with the first channel holes CHH1. Accordingly, a manufacturing cost of the semiconductor device may be reduced by unifying the processes of forming the different types of holes.

Subsequently, a first bonding layer 420 may be formed on the first stack 410S1. For example, the first bonding layer 420 may be formed in a state in which the first channel holes CHH1, the first slit SL1, the first via holes VH1, and the first contact holes CTH1 are empty. In such a case, the first bonding layer 420 may protrude into the first channel holes CHH1, the first slit SL1, the first via holes VH1, and the first contact holes CTH1. The first bonding layer 420 may reduce or prevent entry of foreign substances or the like into the first channel holes CHH1, the first slit SL1, the first via holes VH1, and the first contact holes CTH1.

When a sacrificial material is formed in the first channel holes CHH1, the first slit SL1, the first via holes VH1, and the first contact holes CTH1, the sacrificial material may not be completely removed in a subsequent process. According to an embodiment of the present disclosure, the subsequent process is performed in a state in which the first channel holes CHH1, the first slit SL1, the first via holes VH1, and the first contact holes CTH1 are empty, and it is thus possible to reduce or prevent defects occurring in a process of forming and removing the sacrificial material or the like. The first bonding layer 420 may include an insulating material such as, for example, an oxide or nitride. For example, the first bonding layer 420 may include SiCN.

Referring to FIG. 4B, a second wafer WF2 may be formed. First, a second stack 41052 may be formed on a second substrate 400B. The second stack 410S2 may include third material layers 410A2 and fourth material layers 410B2 that are alternately stacked.

Subsequently, a second bonding layer 430 may be formed on the second stack 410S2. Here, the second bonding layer 430 may include a material that is substantially the same as or different from that of the first bonding layer 420. For example, the second bonding layer 430 may include SiCN.

Subsequently, the first and second wafers WF1 and WF2 may be bonded to each other. For example, the first and second wafers WF1 and WF2 may be bonded to each other so that the first stack 410S1 and the second stack 410S2 face each other. The first and second wafers WF1 and WF2 may be bonded to each other in a state in which the first channel holes CHH1, the first slit SL1, the first via holes VH1, and the first contact holes CTH1 of the first stack 410S1 are empty. In such a case, the first bonding layer 420 and the second bonding layer 430 may be bonded to each other.

For example, a case where the first bonding layer 420 is formed on the first stack 410S1 and the second bonding layer 430 is formed on the second stack 410S2 has been illustrated in FIG. 4B, but it is also possible not to form the first bonding layer 420 and the second bonding layer 430. In such a case, the uppermost first material layer 4210A1 of the first stack 410S1 and the uppermost third material layer 410A2 of the second stack 41052 may be bonded directly to each other.

Referring to FIG. 4C, the second substrate 400B may be removed. Subsequently, a second staircase structure SS2 may be formed in the second stack 41052. For example, the second staircase structure SS2 through which an uppermost surface of at least one of the fourth material layers 410B2 is exposed may be formed. The second staircase structure SS2 of the second stack 410S2 may not overlap with the first staircase structure SS1 of the first stack 410S1 in a stacking direction. For example, the second staircase structure SS2 may not overlap with the first staircase structure SS2 in a vertical direction. A buffer layer BFL may be formed on the fourth material layers 410B2 whose uppermost surfaces are exposed. A second interlayer insulating layer IL2 may be formed on the second staircase structure SS2. The buffer layer BFL may include a material having a selectivity with respect to the third material layers 410A2 and the fourth material layers 410B2. The second interlayer insulating layer IL2 may include an insulating material such as, for example, an oxide.

Second channel holes CHH2 may be formed to extend through the second stack 41052 and may be connected to the first channel holes CHH1. For example, the second channel holes CHH2 may be formed to extend through the second stack 410S2, the second bonding layer 430, and the first bonding layer 420 and exposing the first channel holes CHH1. Here, the first slit SL1, the first via holes VH1, and the first contact holes CTH1 may not be exposed.

Subsequently, channel structures CHS may be formed in the first channel holes CHH1 and the second channel holes CHH2. Each of the channel structures CHS may include at least one of a channel layer CHA, a memory layer CHB surrounding the channel layer CHA, and an insulating core CHC located in the channel layer CHA. When the first channel holes CHH1 are filled with the sacrificial material or the like, the first channel holes CHH1 may be opened by removing the sacrificial material or the like in the first channel holes CHH1 through the second channel holes CHH2, and the channel structures CHS may then be formed. According to an embodiment of the present disclosure, the second channel holes CHH2 are formed in a state in which the first channel holes CHH1 are empty, and thus, an additional process for opening the first channel holes CHH1 before forming the channel structures CHS may be omitted. Accordingly, it is possible to reduce or prevent defects occurring in a process of forming or removing the sacrificial material or the like.

Referring to FIG. 4D, second via holes VH2 may be formed to extend through the second stack 410S2 and may be connected to the first via holes VH1. Subsequently, spacers SP may be formed by oxidizing the second material layers 410B1 and the fourth material layers 410B2 exposed through the first via holes VH1 and the second via holes VH2.

Second contact holes CTH2 extending through the second stack 410S2 and connected to the first contact holes CTH1 may be formed. For example, the second contact holes CTH2 may be formed to extend through the second stack 410S2, the second bonding layer 430, and the first bonding layer 420 and expose the first contact holes CTH1. When the second via holes VH2 are formed, the second contact holes CTH2 may be formed.

A second slit SL2 extending through the second stack 410S2 and connected to the first slit SL1 may be formed. For example, the second slit SL2 extending through the second stack 410S2, the second bonding layer 430, and the first bonding layer 420 and exposing the first slit SL1 may be formed. When the second via holes VH2 are formed, the second slit SL2 may be formed.

According to an embodiment of the present disclosure, the second via holes VH2 may be formed in a state in which the first via holes VH1 are empty, the second contact holes CTH2 may be formed in a state in which the first contact holes CTH1 are empty, and the second slit SL2 may be formed in a state in which the first slit SL1 is empty. Accordingly, it is possible to reduce or prevent defects occurring in a process of forming or removing the sacrificial material or the like.

Referring to FIG. 4E, buffer openings BFOP may be formed by removing the buffer layers BFL disposed on the first staircase structure SS1 and the second staircase structure SS2 through the first via holes VH1 and the second via holes VH2, respectively. Subsequently, contact vias CTV may be formed by forming a conductive material in the first via holes VH1, the second via holes VH2, and the buffer openings BFOP. Here, the conductive material may form protrusion portions CTVP of the contact vias CTV while being filled in the buffer openings BFOP. Consequently, the contact vias CTV respectively connected to the second material layers 410B1 and the fourth material layers 410B2 whose uppermost surfaces are exposed through the first staircase structure SS1 and the second staircase structure SS2 may be formed.

For example, the contact vias CTV have been illustrated in FIG. 4E, but the contact vias CTV may be used as supports. For example, when the channel structures CHS are formed, the supports may be formed instead of the contact vias CTV. In such a case, the supports may include dummy channel structures. For example, the dummy channel structures may each include a dummy channel layer, a dummy memory layer, and a dummy insulating core.

Contact plugs CTP may be formed by forming a conductive material in the first contact holes CTH1 and the second contact holes CTH2. When the contact vias CTV are formed, the contact plugs CTP may be formed. Here, the conductive material may include a conductive material such as, for example, tungsten.

The second material layers 410B1 and the fourth material layers 410B2 may be replaced with fifth material layers 410C through the first slit SL1 and the second slit SL2, respectively. Consequently, a gate structure 410G including the first material layers 410A1 and the fifth material layers 410C that are alternately stacked and the third material layers 410A2 and the fifth material layers 410C that are alternately stacked may be defined. When the second material layers 410B1 and the fourth material layers 410B2 each include a conductive material, a process of replacing the second material layers 410B1 and the fourth material layers 410B2 with the fifth material layers 410C may be omitted. In such a case, the first stack 410S1 and the second stack 410S2 may each be used as the gate structure 410G. Here, the fifth material layers 410C may each include a conductive material such as, for example, tungsten. Subsequently, a slit structure SLS may be formed in the first slit SL1 and the second slit SL2. Here, the slit structure SLS may include at least one of a conductive material, an insulating material, and a semiconductor material.

Subsequently, a third interlayer insulating layer IL3 may be formed on the gate structure 410G. Here, the third interlayer insulating layer IL3 may include an insulating material such as, for example, an oxide. Subsequently, a first interconnection structure IC1 may be formed in the third interlayer insulating layer IL3. The first interconnection structure IC1 may include at least one of a first via 440A and a first wiring line 440B. At least one of the first vias 440A may be connected to the channel structures CHS. At least one of the first vias 440A may be connected to at least one of the contact via CTV and the contact plug CTP. The first interconnection structure IC1 may include a conductive material such as, for example, tungsten.

Subsequently, first bonding pads 450 may be formed on the first interconnection structure IC1. For example, the first bonding pads 450 may be formed over or on the channel structures CHS. The first bonding pads 450 may be formed over or on the contact via CTV and the contact plug CTP. The first bonding pads 450 may be electrically connected to the channel structures CHS, the contact via CTV, and the contact plug CTP through the first interconnection structure IC1. Here, the first bonding pad 450 may include a conductive material such as copper.

Referring to FIG. 4F, a third wafer WF3 may be formed. First, a peripheral circuit PC may be formed on a third substrate 400C. The peripheral circuit PC may include a transistor 1. An element isolation layer ISO may be formed in the third substrate 400C, and may define an active region of the transistor 1.

A second interconnection structure IC2 may be formed on the third substrate 400C. The second interconnection structure IC2 may be formed in a fourth interlayer insulating layer IL4 formed on the third substrate 400C. The second interconnection structure IC2 may include a second via 440C and a second wiring line 440D. The second via 440C may be connected to the peripheral circuit PC. Alternatively, the second via 440C may connect the second wiring lines 440D to each other. The second interconnection structure IC2 may include a conductive material such as, for example, tungsten. The fourth interlayer insulating layer IL4 may include an insulating material such as, for example, an oxide.

Subsequently, second bonding pads 460 may be formed on the second interconnection structure IC2. For example, the second bonding pad 460 may be formed over or on the peripheral circuit PC. The second bonding pads 460 may be electrically connected to the peripheral circuit PC through the second interconnection structure IC2. Here, the second bonding pad 460 may include a conductive material such as copper.

For example, before the second bonding pads 460 are formed, a bonding layer may be further formed on the fourth interlayer insulating layer IL4. The bonding layer may increase bonding force of a bonding interface between the first wafer WF1 and the third wafer WF3 in a subsequent process. Here, the bonding layer may include an insulating material such as SiCN.

Subsequently, the first wafer WF1 and the third wafer WF3 may be bonded to each other, for example, by bonding the first bonding pads 450 and the second bonding pads 460 to each other. The channel structures CHS, the contact vias CTV, and the contact plugs CTP may be electrically connected to the peripheral circuit PC through the first interconnection structure IC1, the first bonding pads 450, the second bonding pads 460, and the second interconnection structure IC2.

Referring to FIG. 4G, the channel structures CHS may be exposed by removing the first substrate 400A. Subsequently, a source structure 470 may be formed on the gate structure 410G. The channel layers CHA may be exposed by partially etching the memory layers CHB of the channel structures CHS. Subsequently, the source structure 470 connected to the channel structures CHS may be formed. Here, the source structure 470 may be connected to the channel layer CHA. A fifth interlayer insulating layer IL5 may be formed at a level corresponding to the source structure 470. For example, the fifth interlayer insulating layer IL5 may be formed on the contact vias CTV and the contact plugs CTP. The fifth interlayer insulating layer IL5 may include an insulating material such as, for example, an oxide.

According to the manufacturing method described above, when the first channel holes CHH1 are formed, the first slit SL1, the first via holes VH1, and the first contact holes CTH1 may be formed simultaneously with the first channel holes CHH1. Accordingly, processes may be unified, and a manufacturing cost of the semiconductor device may be reduced.

In addition, the subsequent process is performed in a state in which the first channel holes CHH1, the first slit SL1, the first via holes VH1, and the first contact holes CTH1 are empty, and it is thus possible to reduce or prevent the defects occurring in the process of forming and removing the sacrificial material or the like.

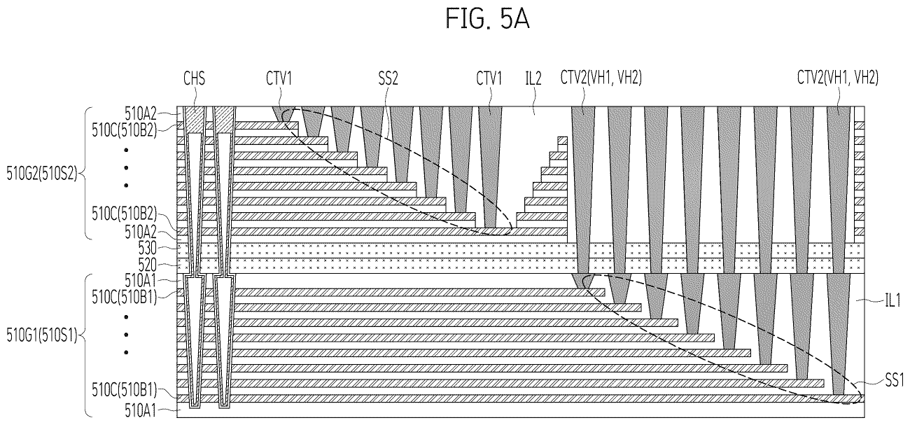

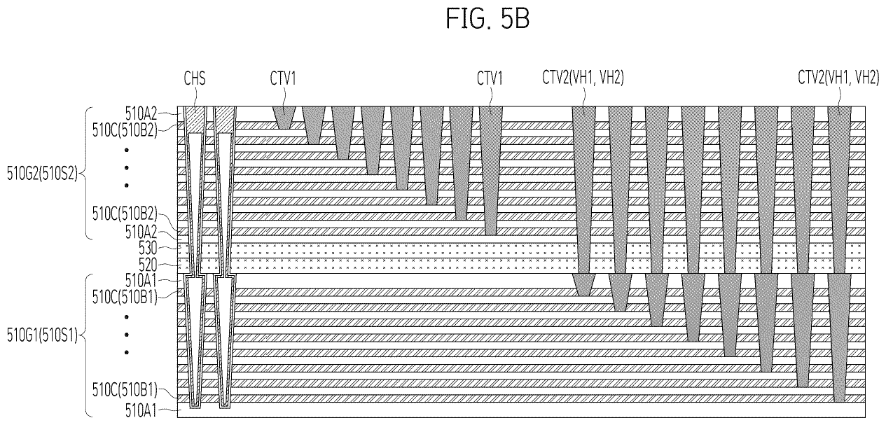

FIGS. 5A and 5B are diagrams for describing a manufacturing method of modified examples of a gate structure 410G and contact vias CTV of FIG. 4E. Hereinafter, content overlapping with previously described content may be omitted.

Referring to FIG. 5A, a first stack 510S1 may be formed including first and second material layers 510A1 and 510B1 that are alternately stacked. Here, the first material layers 510A1 may each include an insulating material such as, for example, an oxide. The second material layers 510B1 may each include a sacrificial material such as, for example, nitride. The first stack 510S1 may include a first staircase structure SS1 exposing each of the second material layers 510B1. A first interlayer insulating layer IL1 may be formed on the first staircase structure SS1.

Subsequently, first via holes VH1 exposing the second material layers 510B1 exposed through the first staircase structure SS1 may be formed. For example, the first via holes VH1 extending through the first interlayer insulating layer IL1 and exposing uppermost surfaces of the second material layers 510B1 may be formed. Here, heights of the first via holes VH1 may be different from each other. For example, the heights of the first via holes VH1 may become greater as the first via holes VH1 become distant from the channel structures CHS.

Subsequently, a first bonding layer 520 may be formed on the first stack 510S1. For example, the first bonding layer 520 may be formed in a state in which the first via holes VH1 are empty. In such a case, the first bonding layer 520 may protrude into the first via holes VH1. The first bonding layer 520 may include SiCN.

A second stack 510S2 including third material layers 510A2 and fourth material layers 510B2 that are alternately stacked may be formed. Here, the third material layers 510A2 may each include an insulating material such as, for example, an oxide, and the fourth material layers 510B2 may each include a sacrificial material such as, for example, nitride. Subsequently, a second bonding layer 530 may be formed on the second stack 510S2. The second bonding layer 530 may include SiCN.

Subsequently, the first bonding layer 520 and the second bonding layer 530 may be bonded to each other so that the first stack 510S1 and the second stack 510S2 face each other. For example, the first bonding layer 520 and the second bonding layer 530 may be bonded to each other in a state in which the first via holes VH1 are empty.

Subsequently, a second staircase structure SS2 may be formed in the second stack 510S2. For example, the second staircase structure SS2 through which an uppermost surface of at least one of the fourth material layers 510B2 is exposed may be formed. The second staircase structure SS2 may not overlap with the first staircase structure SS1 of the first stack 510S1 in the vertical direction. Compared to FIG. 4E, the first staircase structure SS1 in FIG. 4E may be located relatively adjacent to the channel structures CHS, while the first staircase structure SS1 in FIG. 5A may be located relatively distant from the channel structures CHS. The second staircase structure SS2 in FIG. 4E may be located relatively distant from the channel structures CHS, while the second staircase structure SS2 in FIG. 5A may be located relatively adjacent to the channel structures CHS. The first staircase structure SS1 and the second staircase structure SS2 may be variously modified and located so as not to overlap with each other in the vertical direction. A second interlayer insulating layer IL2 may be formed on the second staircase structure SS2.

For example, a third stack (not illustrated) including a third staircase structure may be formed on the second stack 510S2. In such a case, the third staircase structure may be located so as not to overlap with the second staircase structure SS2 in the vertical direction. Here, the third staircase structure may be located to overlap with the first staircase structure SS1 in the vertical direction. That is, when three or more stacks each including a staircase structure are formed, staircase structures of adjacent stacks may be stacked in a zigzag shape so as not to overlap with each other in the vertical direction.

Subsequently, first contact vias CTV1 connected to the fourth material layers 510B2 may be formed. For example, the first contact vias CTV1 connected to the fourth material layers 510B2 exposed through the second staircase structure SS2 may be formed. Here, the first contact vias CTV1 may each include a conductive material such as, for example, tungsten.

Second via holes VH2 connected to the first via holes VH1 may be formed in the second stack 51052. Here, heights of the second via holes VH2 may be substantially the same as each other. Subsequently, second contact vias CTV2 may be formed in the first via holes VH1 and the second via holes VH2. Consequently, the second contact vias CTV2 respectively connected to the second material layers 510B1 of the first stack 510S1 may be formed. Here, the second contact vias CTV2 may each include a conductive material such as, for example, tungsten.

The second material layers 510B1 of the first stack 510S1 and the fourth material layers 510B2 of the second stack 51052 may be replaced with fifth material layers 510C through a slit (not illustrated). Consequently, a first gate structure 510G1 including the first material layers 510A1 and the fifth material layers 510C that are alternately stacked may be formed, and a second gate structure 510G2 including the third material layers 510A2 and the fifth material layers 510C that are alternately stacked may be formed.

Referring to FIG. 5B, a first stack 510S1 including first material layers 510A1 and second material layers 510B1 that are alternately stacked may be formed. Compared to FIGS. 4E and 5A, the first stack 510S1 may not include the first staircase structure SS1.

Subsequently, first via holes VH1 extending through the first stack 510S1 and exposing the second material layers 510B1, respectively, may be formed. Here, heights of the first via holes VH1 may be different from each other. For example, the heights of the first via holes VH1 may become greater as the first via holes VH1 become distant from the channel structures CHS.

Subsequently, a first bonding layer 520 may be formed on the first stack 510S1. For example, the first bonding layer 520 may be formed in a state in which the first via holes VH1 are empty. In such a case, the first bonding layer 520 may protrude into the first via holes VH1. The first bonding layer 520 may include SiCN.

A second stack 510S2 including third material layers 510A2 and fourth material layers 510B2 that are alternately stacked may be formed. Subsequently, a second bonding layer 530 may be formed on the second stack 510S2. The second bonding layer 530 may include SiCN.

Subsequently, the first bonding layer 520 and the second bonding layer 530 may be bonded to each other so that the first stack 510S1 and the second stack 510S2 face each other. For example, the first bonding layer 520 and the second bonding layer 530 may be bonded to each other in a state in which the first via holes VH1 are empty.

Subsequently, first contact vias CTV1 connected to the fourth material layers 510B2 may be formed. For example, the first contact vias CTV1 extending through the second stack 510S2 and connected to the fourth material layers 510B2, respectively, may be formed. Here, the first contact vias CTV1 may each include a conductive material such as, for example, tungsten. Before the first contact via CTV1 is formed, an insulating spacer (not illustrated) may be formed on sidewalls of the first contact via CTV1 in order to prevent the fourth material layers 510B2 other than the fourth material layer 510B2 connected to the first contact via CTV1 from being connected to the first contact via CTV1.

Second via holes VH2 connected to the first via holes VH1 may be formed in the second stack 510S2. Here, heights of the second via holes VH2 may be substantially the same as each other. Subsequently, second contact vias CTV2 may be formed in the first via holes VH1 and the second via holes VH2. Consequently, the second contact vias CTV2 respectively connected to the second material layers 510B1 of the first stack 510S1 may be formed. Here, the second contact vias CTV2 may each include a conductive material such as, for example, tungsten.

Before the second contact via CTV2 is formed, an insulating spacer (not illustrated) may be formed on sidewalls of the second contact via CTV2 in order to prevent the second material layers 510B1 other than the second material layer 510B1 connected to the second contact via CTV2 from being connected to the second contact via CTV2. Here, the second contact vias CTV2 may each include a conductive material such as, for example, tungsten.

The second material layers 510B1 of the first stack 510S1 and the fourth material layers 510B2 of the second stack 510S2 may be replaced with fifth material layers 510C through a slit (not illustrated). Consequently, a first gate structure 510G1 including the first material layers 510A1 and the fifth material layers 510C that are alternately stacked may be formed, and a second gate structure 510G2 including the third material layers 510A2 and the fifth material layers 510C that are alternately stacked may be formed.

According to the manufacturing method described above, locations of the first staircase structure SS1 of the first gate structure 510G1 and the second staircase structure SS2 of the second gate structure 510G2 may be changed. In addition, even though three or more gate structures are formed, staircase structures of adjacent gate structures may be formed so as not to overlap with each other in the vertical direction.

In addition, the first gate structure 510G1 and the second gate structure 510G2 may not include the first staircase structure SS1 and the second staircase structure SS2, respectively. In such a case, insulating spacers may be formed on sidewalls of the first contact vias CTV1 and the second contact vias CTV2 in order to prevent the fifth material layers 510C other than the fifth material layers 510C connected to the first contact vias CTV1 or the second contact vias CTV2 from being electrically connected to the first contact vias CTV1 or the second contact vias CTV2.

Although embodiments according to the technical idea of the present disclosure have been described above with reference to the accompanying drawings, this is only for describing the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure. Furthermore, the embodiments may be combined to form additional embodiments.

What is claimed is:

1. A semiconductor device comprising:
a first gate structure;
a second gate structure located over or on the first gate structure;
a bonding structure located between the first gate structure and the second gate structure; and
a penetration structure extending through the first gate structure, the second gate structure, and the bonding structure.

2. The semiconductor device of claim 1, wherein the penetration structure includes an inflection portion located between the first gate structure and the bonding structure.

3. The semiconductor device of claim 2, wherein the penetration structure includes a first portion extending through the first gate structure and a second portion extending through the second gate structure and connected to the first portion.

4. The semiconductor device of claim 3, wherein the penetration structure includes a tapered shape, and
the first portion has a width that decreases from an uppermost surface of the first gate structure toward a lowermost surface of the first gate structure, and the second portion has a width that decreases from an uppermost surface of the second gate structure toward a lowermost surface of the second gate structure.

5. The semiconductor device of claim 3, wherein the inflection portion is a portion where an uppermost surface of the first portion and a lowermost surface of the second portion are connected to each other, and at the inflection portion, the uppermost surface and the lowermost surface have different widths.

6. The semiconductor device of claim 1, wherein the bonding structure includes a first bonding layer and a second bonding layer disposed on the first bonding layer.

7. The semiconductor device of claim 1, wherein the penetration structure includes at least one of a channel structure, a slit structure, a contact via, and a contact plug.

8. A manufacturing method of a semiconductor device, the manufacturing method comprising:
forming a first wafer including a first substrate, a first stack disposed on the first substrate, and a first opening and a second opening extending through the first stack;
forming a second wafer including a second substrate and a second stack disposed on the second substrate;
bonding the first wafer and the second wafer to each other in a state in which the first opening and the second opening are empty;
forming third openings extending through the second stack and connected to the first opening;
forming fourth openings extending through the second stack and connected to the second opening;
forming a first penetration structure in the first opening and the third opening; and
forming a second penetration structure in the second opening and the fourth opening.

9. The manufacturing method of claim 8, wherein in the bonding of the first wafer and the second wafer to each other, the first wafer and the second wafer are bonded to each other so that the first stack and the second stack face each other.

10. The manufacturing method of claim 8, wherein the first wafer further includes a first bonding layer disposed on the first stack, and
the second wafer further includes a second bonding layer disposed on the second stack.

11. The manufacturing method of claim 10, wherein in the bonding of the first wafer and the second wafer to each other, the first bonding layer and the second bonding layer are bonded to each other.

12. The manufacturing method of claim 10, wherein the first bonding layer or the second bonding layer includes SiCN.

13. The manufacturing method of claim 8, wherein the second opening is formed when the first opening is formed.

14. The manufacturing method of claim 8, wherein the fourth opening is formed when the third opening is formed.

15. The manufacturing method of claim 8, wherein the second penetration structure is formed when the first penetration structure is formed.

16. The manufacturing method of claim 8, wherein the first penetration structure or the second penetration structure includes at least one of a channel structure, a slit structure, a contact via, and a contact plug.

17. A manufacturing method of a semiconductor device, the manufacturing method comprising:
forming a first wafer including a first substrate, a first stack disposed on the first substrate, and first channel holes extending through the first stack;
forming a second wafer including a second substrate and a second stack disposed on the second substrate;
bonding the first wafer and the second wafer to each other in a state in which the first channel holes are empty;
removing the second substrate;
forming second channel holes extending through the second stack and connected to the first channel holes; and
forming channel structures in the first channel holes and the second channel holes.

18. The manufacturing method of claim 17, wherein in the bonding of the first wafer and the second wafer to each other, the first wafer and the second wafer are bonded to each other so that the first stack and the second stack face each other.

19. The manufacturing method of claim 17, wherein the first wafer further includes a first bonding layer disposed on the first stack, and
the second wafer further includes a second bonding layer disposed on the second stack.

20. The manufacturing method of claim 19, wherein in the bonding of the first wafer and the second wafer to each other, the first bonding layer and the second bonding layer are bonded to each other.

21. The manufacturing method of claim 19, wherein the first bonding layer or the second bonding layer includes SiCN.

22. The manufacturing method of claim 17, wherein the first wafer further includes a first slit located between the first channel holes.

23. The manufacturing method of claim 22, wherein the first slit is formed when the first channel holes are formed.

24. The manufacturing method of claim 22, further comprising:
forming a second slit after removing the second substrate, the second slit extending through the second stack and connected to the first slit; and
forming a slit structure in the first slit and the second slit.

25. The manufacturing method of claim 17, wherein the first wafer further includes first contact holes spaced apart from the first channel holes.

26. The manufacturing method of claim 25, wherein the first contact holes are formed when the first channel holes are formed.

27. The manufacturing method of claim 25, further comprising:
forming second contact holes after removing the second substrate, the second contact holes extending through the second stack and connected to the first contact holes; and
forming contact plugs in the first contact holes and the second contact holes.

28. The manufacturing method of claim 17, wherein the first stack includes a first staircase structure, and the first wafer further includes first via holes extending through the first staircase structure.

29. The manufacturing method of claim 28, wherein the first via holes are formed when the first channel holes are formed.

30. The manufacturing method of claim 28, wherein a second staircase structure is formed in the second stack after the second substrate is removed.

31. The manufacturing method of claim 30, further comprising:
forming second via holes extending through the second staircase structure and connected to the first via holes; and
forming contact vias in the first via holes and the second via holes.

32. The manufacturing method of claim 30, wherein the second staircase structure does not overlap with the first staircase structure in a vertical direction.

33. The manufacturing method of claim 17, further comprising forming first bonding pads on the channel structures.

34. The manufacturing method of claim 33, further comprising:
forming a third wafer including a peripheral circuit and second bonding pads disposed on the peripheral circuit;
bonding the first bonding pads and the second bonding pads to each other;
exposing the channel structures by removing the first substrate; and
forming a source structure connected to the channel structures.
